(19) United States
(12) Patent Application Publication
(10) Pub. No.: US 2006/0205359 A1
(43) Pub. Date: Sep. 14, 2006

(54) Lifestyle receiver/transmitter for differentiated consumer product

(76) Inventor: Vincent L. Brooks, Troy, MI (US)

Correspondence Address: DELPHI TECHNOLOGIES, INC., M/C 480-410-202, PO BOX 5052, TROY, MI, 48007, US

(21) Appl. No.: 11/374,693

(22) Filed: Mar. 14, 2006

Related U.S. Application Data
(60) Provisional application No. 60/661,413, filed on Mar. 14, 2005.

(51) Int. Cl. H04B 1/38; H05K 11/00; G08B 1/08

(52) U.S. Cl. 455/73; 455/344; 340/539.1

(57) ABSTRACT

A receiver/transmitter for a consumer product having unique operational features, comprising: a microprocessor programmed to a numerical identifier associated with the consumer product; a housing for housing the microprocessor, the housing being separable from the consumer product; a data transferring component coupled to the microprocessor and configured for communicating with the consumer product; a receiver circuit disposed within the housing; a transmitter circuit disposed within the housing; wherein the microprocessor comprises programmable logic that enables a plurality of signals corresponding to the numerical identifier to be received and transmitted between the consumer product and the receiver/transmitter, wherein the consumer product comprises electrical components necessary to facilitate the receipt and transmission of the plurality of signals, wherein linear dimensions and configurations of the consumer product are not constrained by the microprocessor, the data transferring component, the receiver circuit and the transmitter circuit of the receiver/transmitter and the receiver/transmitter is a stand alone device not capable of providing any of the unique operational features of the consumer product.

### CROSS REFERENCE TO RELATED APPLICATIONS

This application claims the benefit of U.S. Provisional Patent Application Ser. No. 60/661,413 filed Mar. 14, 2005, the contents of which are incorporated herein by reference thereto.

### TECHNICAL FIELD

This present invention relates generally to a receiver/transmitter for use with a consumer product.

### BACKGROUND

Currently, almost everyone carries a portable phone. The phone “form factor” has not changed greatly but has seen tremendous additional features included during the last couple of years. As used herein “form factor” is intended to refer to the linear dimensions and configuration of an item. Examples of the form factors of mobile phones are as follows: Bar—a basic style wherein the entire phone is one solid monolith, with no moving parts except for the buttons and perhaps the antenna; Clamshell: a style wherein the phone consists of two halves, connected by a hinge wherein one half usually contains the speaker and the display while the other half contains the keypad and remaining components. One common feature of these phones is that they include the processing electronics (e.g., receiver/transmitter) and numerical identifier for operation of the phone.

As mentioned above numerous features have been added to portable phones over the last few years. For example, text messages, picture capabilities and wireless Internet features have now been added to some phones. In addition, today's cellular phones also incorporate “push to talk”, MP3 playback, streaming video and gaming functions. Also, the personal digital assistant (PDA) is widely used now and many of theses devices incorporate the phone function into the ultimate product configuration.

In addition, digital broadcast radio such as the satellite digital audio radio service (SDARS) provides subscribers with high quality media services, even in mobile environments like the automobile. The SDARS system uses one or more satellites to broadcast audio and advanced multimedia programs. The satellite broadcasts can be received directly by subscriber receivers at home, at business locations, or in mobile vehicles.

It is now possible to keep your phone number consistent, which in a way, is similar to an identification means, credit card number, social security number, etc. and since the consumer is now typically purchasing a service and a numerical identifier associated with the phone number this allows certain transparency in the phone manufacture as well as the service providers. The number or numerical identifier is the key. This numerical identifier can also be used with other consumer products as mentioned above.

Accordingly, it is desirable to separate the receiver/transmitter componentry having the numerical identifier from the “form factor” of the consumer product wherein both the receiver/transmitter and the consumer product associated with the receiver/transmitter can be adapted for any particular use.

### SUMMARY

Disclosed herein is an apparatus and method for separating the receiver/transmission componentry from the “form factor” of the associated consumer device. This includes the computer chip or microprocessor that identifies an individual number and memory. As disclosed herein these components are redesigned as a single common unit to be configured for use in a whole line of consumer products that will bring connectivity provided by cellular/satellite networks to many differentiated consumer products having various “form factors”. This will allow for continuous connectivity, for a very broad range of personnel and professional activities, without the limitations of current phone “form factors”.

A receiver/transmitter for a consumer product having unique operational features, comprising: a microprocessor programmed to a numerical identifier associated with the consumer product; a housing for housing the microprocessor, the housing being separable from the consumer product; a data transferring component coupled to the microprocessor and configured for communicating with the consumer product; a receiver circuit disposed within the housing; a transmitter circuit disposed within the housing; wherein the microprocessor comprises programmable logic that enables a plurality of signals corresponding to the numerical identifier to be received and transmitted between the consumer product and the receiver/transmitter, wherein the consumer product comprises electrical components necessary to facilitate the receipt and transmission of the plurality of signals, wherein linear dimensions and configurations of the consumer product are not constrained by the microprocessor, the data transferring component, the receiver circuit and the transmitter circuit of the receiver/transmitter and the receiver/transmitter is a stand alone device not capable of providing any of the unique operational features of the consumer product.

A receiver/transmitter for a consumer product having unique operational features, comprising: a microprocessor programmed to a numerical identifier associated with the consumer product; a housing for housing the microprocessor, the housing being separable from the consumer product; a data transferring component coupled to the microprocessor and configured for communicating with the consumer product; a receiver circuit disposed within the housing; a transmitter circuit disposed within the housing; wherein the microprocessor comprises programmable logic that enables a plurality of signals corresponding to the numerical identifier to be received and transmitted between the consumer product and the receiver/transmitter, wherein the consumer product comprises electrical components necessary to facilitate the receipt and transmission of the plurality of signals, wherein linear dimensions and configurations of the consumer product are not constrained by the microprocessor, the data transferring component, the receiver circuit and the transmitter circuit of the receiver/transmitter and the receiver/transmitter is a stand alone device not capable of providing any of the unique operational features of the consumer product.

A system for receipt and transmission of a plurality of signals, the system comprising: a family of consumer products each being configured to exchange data with a portable receiver/transmitter, wherein the portable receiver/transmitter, comprises: a microprocessor programmed to a numerical identifier associated with each of the family of consumer products and each of the family of consumer products provides unique operational features; a housing for housing the microprocessor, the housing being separable from the consumer product; a data transferring component coupled to the microprocessor and configured for communicating with each of the family of consumer products; a receiver circuit disposed within the housing; a transmitter circuit disposed within the housing; wherein the microprocessor comprises programmable logic that enables a plurality of signals corresponding to the numerical identifier to be received and transmitted between each of the family of consumer products and the portable receiver/transmitter, wherein each of the family of consumer products comprises electrical components necessary to facilitate the receipt and transmission of the plurality of signals and the microprocessor further comprises machine-readable code for implementing the steps of: searching for at least one of the family of consumer products by transmitting radio waves at a frequency in a predetermined range; establishing a communication link between at least one of the family of consumer products and the receiver/transmitter to create a linked consumer product wherein data is exchanged between the linked consumer product and the receiver/transmitter; inquiring whether an account is to be accessed by the linked consumer product utilizing the numerical identifier; and providing the numerical identifier to the linked consumer product to allow for access to the account, wherein the numerical identifier is an encrypted digital certificate; and wherein linear dimensions and configurations of the consumer product are not constrained by the microprocessor, the data transferring component, the receiver circuit and the transmitter circuit of the portable receiver/transmitter.

A method for accessing a plurality of consumer products with a single receiver/transmitter, comprising: searching for at least one of the plurality of consumer products by transmitting radio waves from the receiver/transmitter; establishing a communication link between at least one of the consumer products and the receiver/transmitter to create a linked consumer product wherein data is exchanged between the linked consumer product and the receiver/transmitter; inquiring whether an account is to be accessed on the linked consumer product; and providing a numerical identifier to the linked consumer product to allow for access to the account, wherein the numerical identifier is an encrypted digital certificate and the receiver/transmitter is a stand alone device not capable of providing any of the operational features of the plurality of consumer products.

The above-described and other features of the present disclosure will be appreciated and understood by those skilled in the art from the following detailed description, drawings, and appended claims.

### DRAWINGS

FIG. 1 is a schematic illustration of a receiver/transmitter of an exemplary embodiment of the present invention communicating with a plurality of consumer products;

FIG. 2 is a schematic illustration of a receiver/transmitter in accordance with an exemplary embodiment of the present invention;

FIG. 3 is a schematic illustration of a receiver/transmitter in accordance with an alternative exemplary embodiment of the present invention;

FIGS. 4-6 illustrate consumer products capable of being used with the lifestyle receiver/transmitter in accordance with exemplary embodiments of the present invention;

FIGS. 7-10 are perspective views of a lifestyle receiver/transmitter constructed in accordance with an exemplary embodiment of the present invention;

FIG. 11 is a flow chart illustrating portions of a control algorithm for use with exemplary embodiments of the present invention; and

FIG. 12 is a schematic illustration of another exemplary embodiment of the present invention.

### DESCRIPTION OF EXEMPLARY EMBODIMENTS

Disclosed herein is a method and apparatus for controlling and/or providing access to a consumer product through user identification and authentication. Also disclosed herein is a receiver/transmitter configured to provide access to a plurality of consumer products each being linkable to the receiver/transmitter thus, a single receiver/transmitter provides a user access to many consumer products, which may be located in various areas remote from each other as well as portable products. For example, each of the consumer products will be configured to receive and transmit data to and from the lifestyle receiver/transmitter thus, the lifestyle receiver/transmitter will allow an individual to have access to a plurality of consumer products wherein the “form factor” of the consumer product can be varied as the same is not constrained to traditional styles since the required receiver/transmitter is removed from the consumer product and is now in the lifestyle receiver/transmitter. For example, by removing the receiver/transmitter comprising a numerical identifier from a consumer product the consumer product itself can be manufactured to any suitable configuration, as the “form factor” of the device is no longer limited by the constraints of having all of the components of the receiver/transmitter therein. Moreover, the lifestyle receiver/transmitter of exemplary embodiments of the present invention will allow remote access to user accounts that are presently limited to stand alone locations such as an individual's home or vehicle (e.g., consumer devices that are not typically portable but have user subscriptions wherein content or data access varies with type of subscriber accounts (e.g., premium, basic, etc.)).

In accordance with an exemplary embodiment, the lifestyle receiver/transmitter is configured for use with systems and/or may comprise a portable portion of a system. Non-limiting examples of systems include, but are not limited to any of the following: computer systems (e.g., laptop, desktop, hand-held, server, mainframe, etc.), video systems (e.g., scanners, digital cameras, video cameras, etc.), television systems (e.g., control boxes for cable or satellite signals), wireless communication systems (e.g., cellular phones), or a consumer electronic appliance. As defined herein a “processor” includes logic capable of being programmed and processing information such as a microprocessor, a microcontroller, a state machine and the like. A “bus” is generally defined as any medium over which information may be transferred such as, for example, electrical wire, optical fiber, cable, wireless (e.g., satellite, radio frequency “RF”, infrared, etc.) and the like. “Information” is defined as data, address, control or any combination thereof.

In order to perform the prescribed functions and desired processing, as well as the computations therefore (e.g., the execution of fourier analysis algorithm(s), the control processes prescribed herein, and the like), the lifestyle receiver/transmitter may include, but is not limited to, a processor(s), computer(s), memory, storage, register(s), timing, interrupt(s), communication interfaces, and input/output signal interfaces, as well as combinations comprising at least one of the foregoing.

For example, the lifestyle receiver/transmitter may include input signal filtering to enable accurate sampling and conversion or acquisitions of such signals from communications interfaces. As described above, exemplary embodiments of the present invention can be implemented through computer-implemented processes and apparatuses for practicing those processes.

In accordance with exemplary embodiments of the present invention the lifestyle receiver/transmitter and/or consumer product will comprise control interface configurations and related control algorithms for responding to inputs received. One device would be resident within the lifestyle receiver/transmitter and the other if necessary would be associated with the consumer product. The microprocessor and/or equivalent devices comprise among other elements read only memory in the form of an electronic storage medium for executable programs or algorithms and calibration values or constants, random access memory and data buses for allowing the necessary communications (e.g., input, output and within the microprocessor) in accordance with known technologies. For example one microprocessor and necessary hardware will be resident in the lifestyle receiver/transmitter wherein a control algorithm of exemplary embodiments of the present invention will be implemented.

It is understood that the processing of the above description may be implemented by a controller operating in response to a computer program, in order to perform the prescribed functions and desired processing, as well as the computations therefore, the controller may include, but not be limited to, a processor(s), computer(s), memory, storage, register(s), timing, interrupt(s), communication interfaces, and input/output signal interfaces, as well as combinations comprising at least one of the foregoing.

As described above, the algorithms for implementing exemplary embodiments of the present invention can be embodied in the form of computer-implemented processes and apparatuses for practicing those processes, wherein the computer program code is loaded into and executed by the microprocessor and the lifestyle receiver/transmitter becomes an apparatus for practicing exemplary embodiments of the present invention. In one non-limiting exemplary embodiment, the processor will comprise reprogrammable storage (e.g., flash memory) that can be updated to implement various aspects of command code and the algorithms can also be embodied in the form of computer program code, for example, whether stored in a storage medium, loaded into and/or executed by a computer, or transmitted over some transmission medium, such as over electrical wiring or cabling, through fiber optics, or via electromagnetic radiation, wherein, when the computer program code is loaded into and executed by the lifestyle receiver/transmitter. When implemented on a general-purpose microprocessor, the computer program code segments configure the microprocessor to create specific logic circuits. These instructions may reside, for example, in RAM of the lifestyle receiver/transmitter.

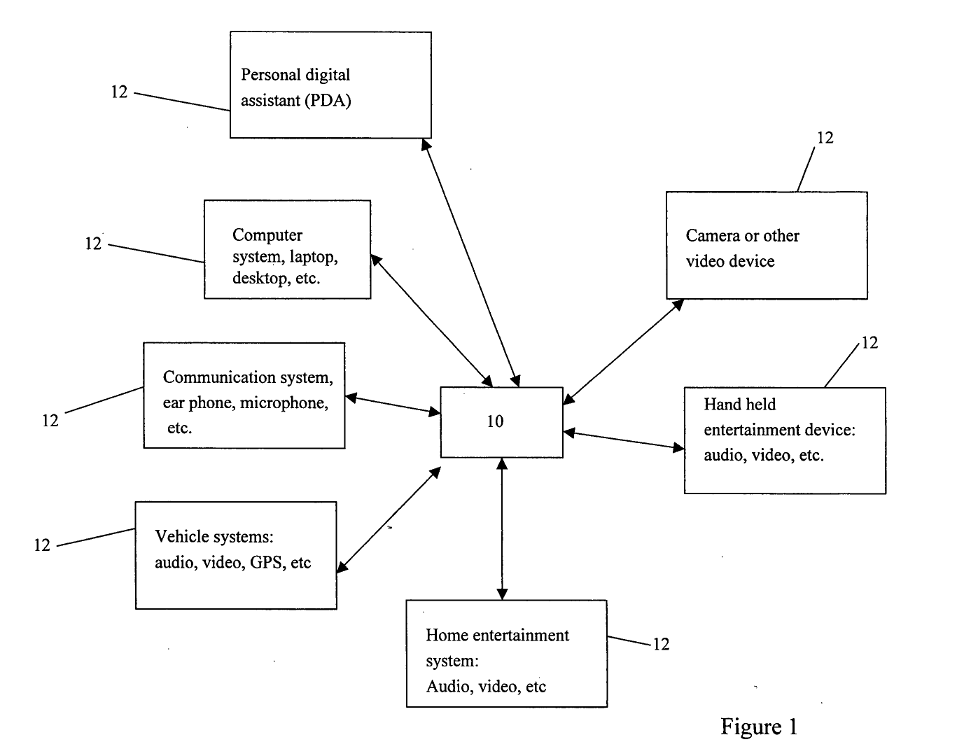

An exemplary embodiment of the present invention is shown schematically in FIG. 1. As illustrated, a receiver/transmitter 10 is configured to communicate and/or provide data inputs to at least one of a plurality of consumer products 12. Each of the consumer products is configured to communicate with receiver/transmitter 10. In accordance with an exemplary embodiment, each of the consumer products provides a unique operational feature. In an exemplary embodiment receiver/transmitter 10 comprises electronic circuitry or a system for facilitating either wirelessly or by direct connection, information that will enable a user to operate or access one of the systems of a plurality of consumer products 12 wherein this electronic circuitry or system is removed from the consumer product thus, allowing the “form factor” or linear dimensions and configuration of the consumer product to vary. As used herein access is intended to allow data and/or information to be provided to and/or from the consumer device, wherein electrical communication is facilitated. For example, streaming video and audio signals can be provided to a display device such as a television or alternatively an audio signal can be provided to a radio or other device capable of converting the received signal into an audio format.

Non-limiting examples of consumer products 12 include: personal digital assistants (PDAs); computer systems (e.g., laptops, desktops, servers, mainframes, etc); communication systems (e.g., phones, pagers, two way radios, cellular phones, voice over Internet protocol (VOIP), etc.); vehicle systems (e.g., audio entertainment, video entertainment, tracking devices, global positioning systems, Onstar, satellite digital audio radio systems (SDARS)); home entertainment systems (e.g., audio entertainment, video entertainment, cable television, satellite TV, satellite digital audio radio systems (SDARS)); and cameras or other video devices; hand held entertainment devices, any of which may be adapted to communicate with Internet service providers (ISPs) as well as be incorporated into a wearable item including but not limited to watches, headsets, necklaces, helmets, backpacks, belts, wallets etc.

Moreover, each of these consumer products can be configured to receive information (e.g., audio signals, video signals, etc.) and provide unique operational features associated with the particular function of the consumer product. For example, a satellite digital audio radio system (SDARS) is capable of receiving and providing audio content which is a non-limiting exemplary example of a unique operational feature of a consumer product comprising a satellite digital audio radio system. In yet another example a microphone and earpiece are also capable of receiving and providing audio content which is a non-limiting exemplary example of a unique operational feature of a consumer product comprising an earpiece and microphone. In yet another example, a satellite digital video system is capable of receiving and providing audio and video content which is a non-limiting exemplary example of a unique operational feature of a consumer product comprising a satellite digital video system alternatively the signal may be provided by cable or other wireless transmission. Other consumer products providing unique operational features associated with the use of the same include features necessary for using personal digital assistants (PDAs); computer systems (e.g., laptops, desktops, servers, mainframes, etc); communication systems (e.g., phones, pagers, two way radios, cellular phones, voice over Internet protocol (VOIP), etc.); vehicle systems (e.g., audio entertainment, video entertainment, tracking devices, global positioning systems, Onstar, satellite digital audio radio systems (SDARS)); home entertainment systems (e.g., audio entertainment, video entertainment, cable television, satellite TV, satellite digital audio radio systems (SDARS)); cameras or other video devices; and hand held entertainment devices wherein the operational features of the consumer product are not directly provided by the lifestyle receiver/transmitter.

In accordance with an exemplary embodiment, each of these consumer products will be configured to have an operating system or operational protocol to interface with receiver/transmitter 10 thus; a single receiver/transmitter 10 will provide a user with access to any of these devices and the numerical identifier of the lifestyle receiver/transmitter will allow unique operational features associated with the particular function of the consumer product to be available. In other words, the numerical identifier of the lifestyle receiver/transmitter will “unlock” the consumer product so the owner or user of the lifestyle receiver/transmitter will be able to use/access the unique operational features of the consumer product. Moreover and in accordance with an exemplary embodiment, the lifestyle receiver/transmitter is not capable of providing the unique operational features of the consumer products as it merely provides the numerical identifier to gain access to the consumer product.

In addition, each of these devices will be configured to interface with receiver/transmitter 10 thus providing a line of consumer products each having a differentiated “form factor”. In other words by separating the componentry of the receiver/transmitter from the consumer product it is now possible to change the “form factor” of the consumer product from more traditional styles that are constrained to that products particular “form factor“(i.e., consumer products that are manufactured with an integral receiver/transmitter and numerical identifier).

In one exemplary embodiment receiver/transmitter 10 will allow a user to securely access a consumer product remote from their residence or a consumer product not owned by the owner of the receiver/transmitter 10 by use of an encrypted digital certificate of the receiver/transmitter wherein the same is transmitted via predetermined communication protocol.

For example, and in accordance with an exemplary embodiment, a first user who is the owner of a receiver/transmitter 10 and has an existing account associated with one of the consumer products (e.g., a satellite digital radio system), will have the receiver/transmitter programmed to their unique identifier code that will enable them to use their account with consumer products adapted for this product (e.g., satellite digital radio system of a line of products 12), which are configured to interface either directly or wirelessly with the receiver/transmitter 10.

In other words an owner of receiver/transmitter 10, programmed for use with an existing satellite digital radio system account, will be able to play/utilize their account on a consumer product that may not be owned by the owner of receiver/transmitter 10. Moreover, the lifestyle receiver/transmitter is not capable of providing these features however, the same is easily stowed in an article of clothing of the user. For example, a first user with a programmed receiver/transmitter may access their satellite digital radio system account on a satellite radio of their friend's car or other location, wherein all of the information and features of the first user's account can be communicated to the satellite radio of the second person's consumer product via the numerical identifier supplied by the lifestyle receiver/transmitter. This is but one example of exemplary embodiments of the present invention. Accordingly, such access may allow certain features of the first user's account to be played on the device of the second person as long as the receiver/transmitter is either directly coupled to the consumer product or with a limited range of wireless transmission wherein a digitally encrypted signal may be received. Furthermore, the consumer product may also be configured with an interface wherein an authorization, either password enabled or simply inputted, is required prior to use with receiver/transmitter 10 so that receiver/transmitter does not override an existing account of a consumer product 12. This may be particularly useful in the wireless embodiment of the present invention.

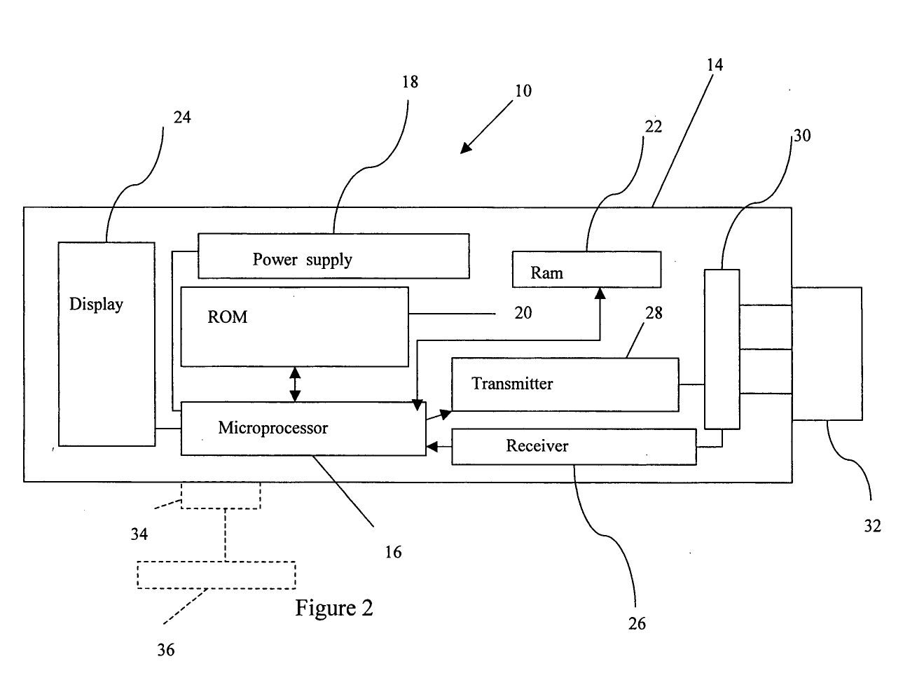

Referring now to FIG. 2, a non-limiting configuration of receiver/transmitter 10 is illustrated schematically. Receiver/transmitter 10 comprises a housing 14 for containing the required electronics of receiver/transmitter 10. In an exemplary embodiment receiver/transmitter 10 will comprise at least one programmable microprocessor 16 in electrical communication with a power supply 18, read only memory 20, random access memory 22, and a display device 24. In addition, the microprocessor will also be in electrical and/or other communication (RF) to receive signals from a receiver and/or receiver circuit 26 and a transmitter and/or a transmitter circuit 28.

In accordance with an exemplary embodiment, receiver circuit 26 and transmitter circuit 28 comprise an integrated circuit and other electrical components necessary to receive and transmit signals and information through a data bus 30 that is coupled to a data transferring component 32, which in one embodiment is mounted externally to housing 14 in order to allow direct coupling to one of the consumer products 12. As is known to those skilled in the related arts such components may comprise amplifiers, converters (analog to digital, etc), antennas, comparators, transistors, gain controllers, as well as resistors, capacitors and inductors in order to facilitate receipt and transmission of data signals. Furthermore, each of the aforementioned components are secured to a motherboard or other equivalent device comprising an integrated circuit to facilitate the operation of the receiver/transmitter. In accordance with an exemplary embodiment, signals are received wirelessly and transmitted either wirelessly or through direct connection to the consumer product.

In accordance with an exemplary embodiment data transferring component 32 may comprise a universal serial bus (USB) connector or other equivalent connector for coupling to a USB port or other equivalent connector of one of the consumer products. Alternatively, data transferring component 32 may comprise an antenna for wirelessly transmitting data signals. In this embodiment the antenna may be mounted either internally or externally to housing 14.

In addition, programmable microprocessor 16 is configured to also be programmed either wirelessly or through a direct interface that may be facilitated by data transferring component 32. Alternatively, and as illustrated by the dashed lines in FIG. 2, an additional data transferring component 34 may be provided on housing 14 in order to input data into microprocessor 16. Data transferring component 34 may also provide an interface for a keyboard or other input device 36. Alternatively, keyboard or other input device 36 may comprise a portion of the exterior of the housing 14 or in yet another alternative embodiment display 24 is a touch screen capable of providing data input as well as visual displays. For example, receiver/transmitter 10 may be password enabled to prevent unauthorized use of the same.

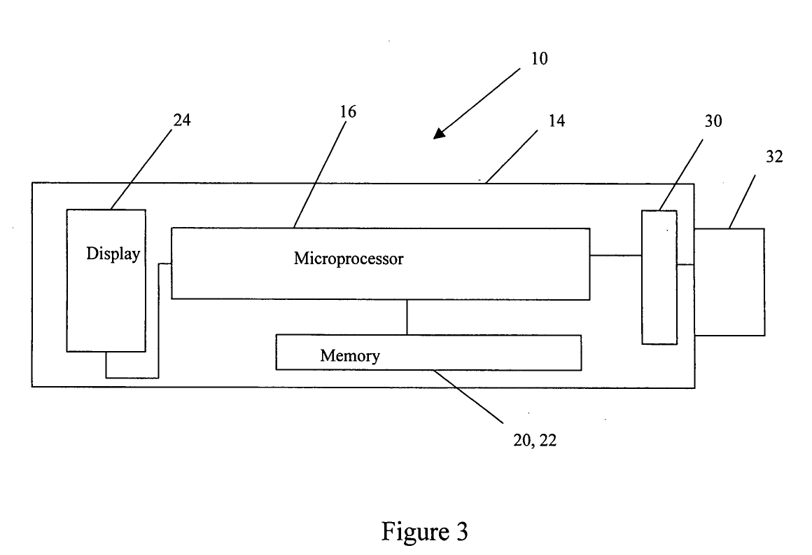

In an alternative exemplary embodiment and referring now to FIG. 3, the receiver/transmitter is only a plug-in device that only includes a number chip or microprocessor 16 similar to that of current cellular phone providers. Thus, the receiver/transmitter is only a plug-in device and the power requirements and antenna reside in the line of consumer products to which this receiver/transmitter is supplied.

Therefore, and since exemplary embodiments of the present invention allow stylized products to be developed to various consumer products various “form factors” not limited to those of existing devices (e.g., cell phones) may be provided. Furthermore, it might even be possible to wear the receiver/transmitter in any number of suitably designed fashion articles.

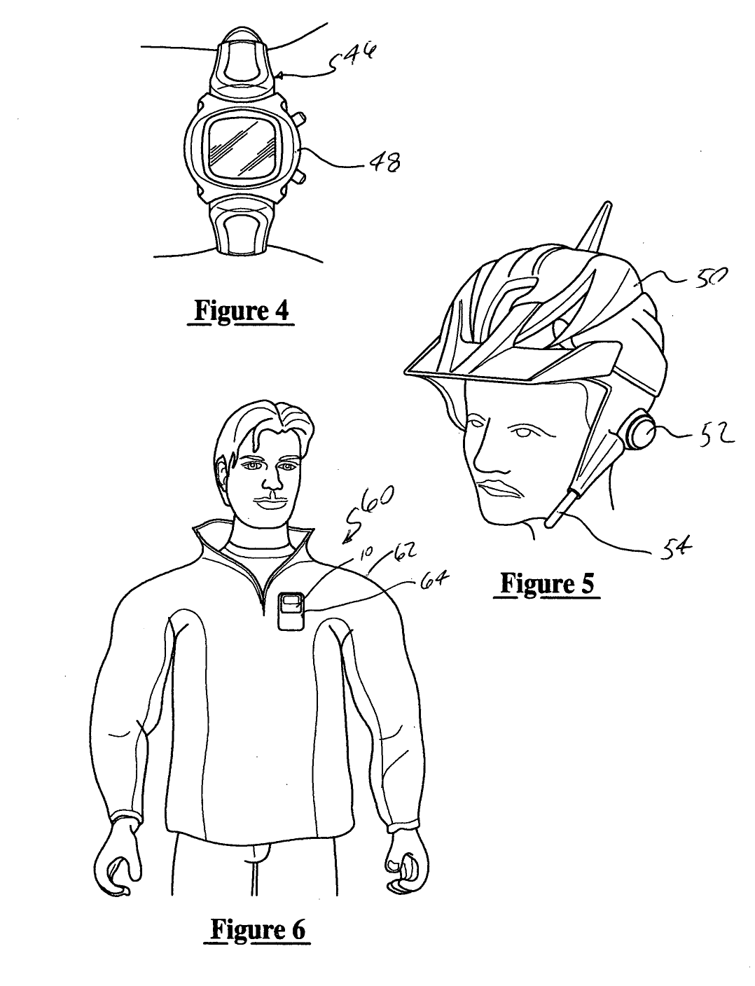

For example and referring now to FIGS. 4-6, non-limiting examples of consumer products capable of being used with the lifestyle receiver/transmitter in accordance with exemplary embodiments of the present invention are illustrated. FIG. 4 illustrates a wristband 46 with an electronic device 48, which may comprise a heart rate monitor, global positioning system (GPS) device, stop watch etc. each of which may comprise a subscriber network that is accessed or turned on by the proximity of the lifestyle receiver/transmitter.

FIG. 5 illustrates a helmet 50 that is equipped with an earpiece 52 and a microphone 54. Accordingly, helmet 50 may be configured to communicate with lifestyle receiver/transmitter thus, and as discussed herein the numerical identifier of the lifestyle receiver/transmitter will allow the microphone and earpiece of the helmet to be used with any one of an audio communication device (e.g., cellular phone network, two way radio or playing of digital music).

In FIG. 6, a user 60 is shown with an article of clothing 62, comprising a discrete location 64 for receipt of the lifestyle receiver/transmitter. Of course, other wearable articles of clothing are contemplated to be used with exemplary embodiments of the present invention (e.g., hats, wristbands, belts, glasses, wallets, backpacks, etc.).

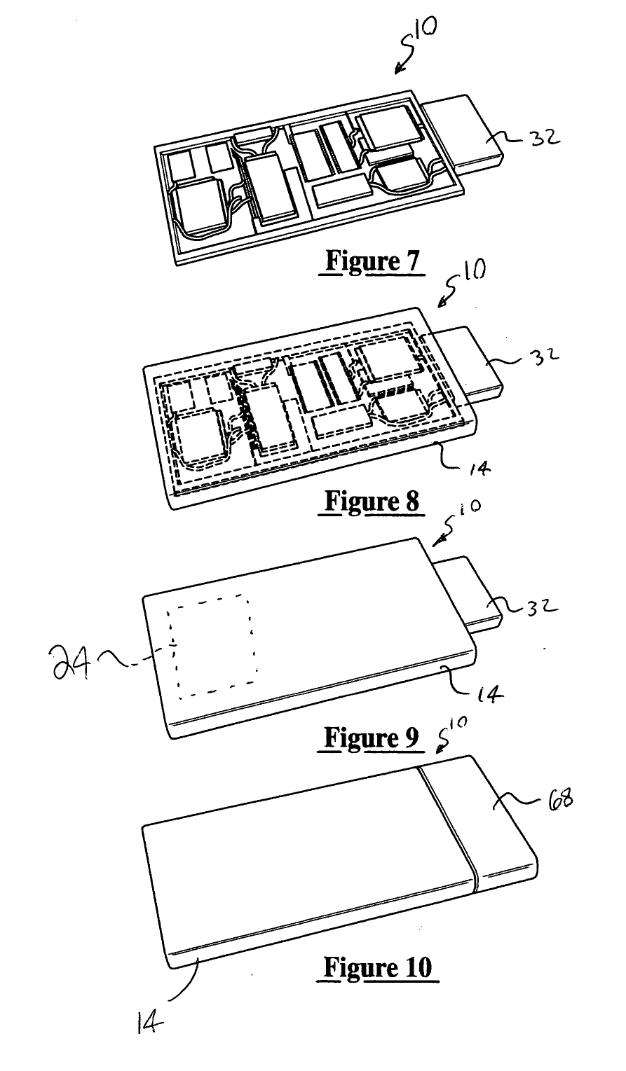

FIGS. 7-10 are perspective views of a lifestyle receiver/transmitter constructed in accordance with an exemplary embodiment of the present invention. As illustrated, lifestyle receiver/transmitter 10 will comprise at least one programmable microprocessor in electrical communication with a power supply, read only memory, random access memory, and a display device 24. In one embodiment and as illustrated by the dashed lines in FIG. 9, display device 24 is located on an exterior surface of housing 14. In another embodiment, lifestyle receiver/transmitter is constructed without a display device. In addition, the microprocessor will also be in electrical and/or other communication (RF) to receive signals from a receiver and/or receiver circuit and a transmitter and/or a transmitter circuit.

In accordance with an exemplary embodiment, receiver circuit and transmitter circuit comprise an integrated circuit and other electrical components necessary to receive and transmit signals and information through a data bus that is coupled to a data transferring component 32, which in one embodiment is mounted externally to housing 14 in order to allow direct coupling to one of the consumer products 12.

Housing 14 will in one embodiment comprise a removable cover 68 for covering data transferring component 32.

With the increased use of BLUETOOTH headsets, and voice recognition, consumers can benefit from a line of products that they can choose based on their lifestyle thus, the receiver/transmitter of exemplary embodiments of the present invention allow the consumer to decide on their particular “form factor”, which may not be based upon a particular style of consumer products (e.g., phone or personal digital assistant). Thus, the lifestyle receiver/transmitter of exemplary embodiments of the present invention will allow users to select consumer products from a family of consumer products adapted to communicate with the lifestyle receiver/transmitter wherein depending on the user's lifestyle (e.g., active, non-active, handicapped) the particularly suited consumer product with a suitable “form factor” may be selected.

For example, BLUETOOTH technology and networking transmits data via low-power RF signals at a frequency of between 2.402 GHz and 2.480 GHz, which has been set aside by international agreement for the use of industrial, scientific and medical devices (ISM).

BLUETOOTH can connect up to numerous devices simultaneously as it uses a technique called spread-spectrum frequency hopping that makes it rare for more than one device to be transmitting on the same frequency at the same time. For example, a single device may use 79 individual, randomly chosen frequencies within a designated range, changing from one to another on a regular basis. In the case of BLUETOOTH, the transmitters change frequencies 1,600 times every second, thus many devices can make full use of a limited area of this radio spectrum. Since every BLUETOOTH transmitter uses spread-spectrum transmitting automatically, it's unlikely that two transmitters will be on the same frequency at the same time.

When BLUETOOTH-capable or other electronic devices come within range of one another, an electronic conversation or exchange of information takes place to determine whether they have data to share or whether one needs to control the other. This electronic exchange happens automatically. Once the exchange occurs the devices form a network that may fill a discrete area or may encompass a small distance between a user's head and waist. Once the network is established, the members or devices in the network randomly change frequencies in unison so they can communicate with each other as well as avoid other networks in same area.

Accordingly, the lifestyle receiver/transmitter using BLUETOOTH or other equivalent technology will be able to communicate with a consumer product and thus allow for access to numerous devices as well as allowing for the “form factor” of the various consumer products to be changed and therefore provide increased consumer selectivity.

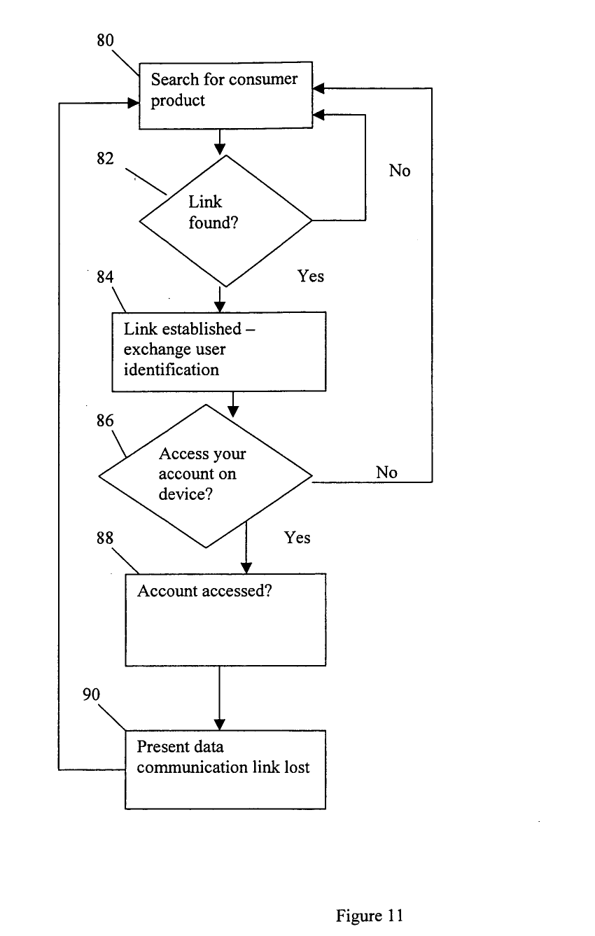

For example and referring now to the flowchart of FIG. 11, an example of an exemplary embodiment of the present invention is illustrated. FIG. 11 provides a non-limiting example of portions of a control algorithm resident upon a microprocessor of a lifestyle receiver/transmitter in accordance with an exemplary embodiment of the present invention. Here the lifestyle receiver/transmitter searches for a consumer product using BLUETOOTH or any other equivalent protocol. This is represented by step 80 and can occur continuously or periodically as may be set by a user input. Furthermore, the lifestyle receiver/transmitter can be configured to search at different rates, manually or automatically. At step 82 the lifestyle receiver/transmitter queries if a link has been found. At step 84, the lifestyle receiver/transmitter has established a link or exchange of information with a consumer product (e.g., personal digital assistants (PDAs); computer systems (e.g., laptops, desktops, servers, mainframes, etc); communication systems (e.g., phones, pagers, two way radios, cellular phones, voice over Internet protocol (VOIP), etc.); vehicle systems (e.g., audio entertainment, video entertainment, tracking devices, global positioning systems, Onstar, satellite digital audio radio systems (SDARS)); home entertainment systems (e.g., audio entertainment, video entertainment, cable television, satellite TV, satellite digital audio radio systems (SDARS)); and cameras or other video devices; hand held entertainment devices).

Thereafter, and in accordance with an exemplary embodiment lifestyle receiver/transmitter 10 provides the appropriate user identification (e.g., numerical identifier or digital certificate) to the consumer product, which as discussed above may be a cellular phone network or other device and the user identification provides the account information for operation of the consumer product. Another non-limiting example is that the lifestyle receiver/transmitter exchanges information with a satellite radio, wherein the satellite radio will allow access to any subscriber network of the owner of the lifestyle receiver/transmitter. This step is represented by box 84. Providing the user identification is key as the appropriate information for allowing access to the consumer product is provided.

In one exemplary embodiment, the families of consumer products are not capable of operating unless the numerical identifier is received from the lifestyle receiver/transmitter. Thus, and in this embodiment, and in order to access or activate/use one of these consumer products the user must have a lifestyle receiver/transmitter with the appropriate numerical identifier. Moreover, the lifestyle receiver/transmitter itself will not be capable of providing the unique operational features of the consumer products.

Furthermore and if the consumer product is a device intended for use with a subscriber network, the control algorithm of the lifestyle receiver/transmitter may be configured to provide a query to the operator wherein the following question is offered in either text or audio format “Do you wish to access your ______ account?” or “Hello [NAME] would you like to enable your account on this device?” wherein the account is identifiable with the consumer product (e.g., subscriber information). This is represented by box 86 and if the answer is yes the account is accessed at step 88 or alternatively the device can go back to its searching mode if the answer is no. The device can also be configured to re-ask the same question or discontinue the question if the answer is no for more than a predetermined number of times. Alternatively, the system is configured to not have step 86 and the lifestyle receiver/transmitter automatically establishes a link with the consumer product once the appropriate exchange of information has taken place.

Once a data transfer or communication link is lost at step 90, the device will return to its searching mode.

In accordance with an exemplary embodiment the lifestyle receiver/transmitter is programmed to communicate with numerous devices until a desired communication link is established with a specific device and the user identifier information is passed through to the consumer product allowing usage of the same.

Moreover, the lifestyle receiver/transmitter can establish multiple separate networks, each one made up of devices that respond to a specific address of the transmitter of the lifestyle receiver/transmitter wherein user identification information is passed onto the consumer product. In addition, since each device is changing the frequency of its operation thousands of times a second, it will be unlikely that any two consumer products will be trying to communicate with the lifestyle receiver/transmitter on the same frequency at the same time.

Other non-limiting methods or protocols that can be utilized for transferring the signals between, receiver/transmitter 10 and at least one consumer product include: ANT—Low Data Rate Low Power wireless personal area network; KNX—intelligent electrical installation networking; HomePlug—powerline protocol; IrDA—industry standard infrared protocol; INSTEON—an integrated dual-band mesh network that combines wireless radio frequency (RF) with the home's existing electrical wiring; nanoNET[4]—proprietary set of wireless sensor protocols, designed to compete with ZigBee; OBEX—communications protocol that facilitates the exchange of binary objects between devices; RadioRa—proprietary two-way RF protocol, developed by Lutron for use in residential lighting control; TinyOS—mesh network OS using the NesC language; Topdog—proprietary protocol for wireless networking, for use in residential and commercial lighting control; UPB—powerline protocol that offers improved performance and reliability over X10; Wi-Fi—product compatibility standards for wireless local area networks (WLANs); Wireless USB—wireless extension to USB; X10—powerline protocol; Z-wave—proprietary protocol for wireless home control networking; and ZigBee—a set of high level protocols designed for low power digital radios.

As used herein the term “secure” and/or “encrypted” generally indicates a state where it is extremely difficult for an unauthorized individual to access the information being transmitted wherein an encoding and/or decoding parameter of binary data is provided and/or required for the data transfer.

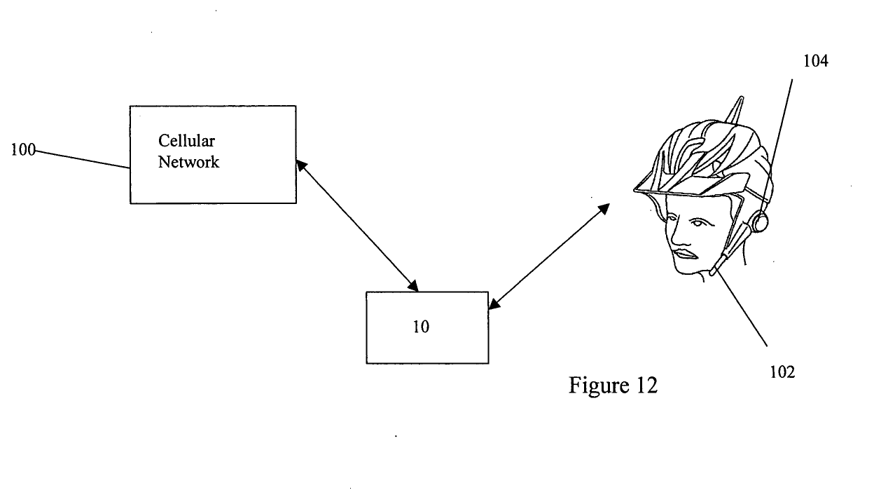

In yet another alternative exemplary embodiment and referring to FIG. 12, the lifestyle receiver/transmitter is configured to receive and transmit signals into a cellular network 100 and the lifestyle receiver/transmitter is configured to provide some of these signals to and from a microphone 102 and an earpiece 104 wherein the microphone and earpiece are not limited by the “form factor” of current cellular phones. Moreover, the lifestyle receiver/transmitter will also be configured to receive signals from the microphone and the earpiece. Thus, the consumer product (e.g., microphone 102 and earpiece 104) may be integrated into a wearable item of clothing as they are not limited by traditional “phone factors”. Of course, the lifestyle receiver/transmitter can be configured to receive and transmit signals into another network or system and the lifestyle receiver/transmitter is configured to provide these signals from the network to a consumer product associated with the network wherein the consumer product is not limited by traditional “form factors”. Moreover, the lifestyle receiver/transmitter will also be configured to receive signals from the consumer product.

In one non-limiting alternative exemplary embodiment the lifestyle receiver/transmitter is the receiver/transmitter is a stand-alone device not capable of providing any of the features of the plurality of consumer products and in this embodiment, the lifestyle receiver/transmitter is merely a device for enabling or facilitating the features of one of the consumer products.

While the invention has been described with reference to an exemplary embodiment, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. A receiver/transmitter enabling device for a consumer product having unique operational features, comprising:
a microprocessor programmed to a numerical identifier associated with the consumer product;
a housing for housing the microprocessor;
a data transferring component coupled to the microprocessor and configured for communicating with the consumer product, the housing being separable from the consumer product; and
wherein the microprocessor comprises programmable logic that enables a plurality of signals corresponding to the numerical identifier to be received and transmitted to and from the consumer product, and wherein the consumer product comprises electrical components necessary to facilitate the receipt and transmission of the plurality of signals, wherein linear dimensions and configurations of the consumer product are not constrained by the microprocessor and the data transferring component of the receiver/transmitter enabling device and the receiver/transmitter enabling device is a stand alone device not capable of providing any of the unique operational features of the consumer product.

2. The receiver/transmitter enabling device as in claim 1, wherein the consumer product is an earpiece and microphone and the receiver/transmitter enabling device is configured to receive signals from a cellular phone network.

3. The receiver/transmitter enabling device as in claim 1, wherein the consumer product is a video display and the plurality of signals are a subscription of video programming for display on the video display and the unique operational features are video display of the plurality of signals.

4. The receiver/transmitter enabling device as in claim 1, wherein the consumer product is a personal digital assistant and the plurality of signals are a subscription to a wireless network.

5. The receiver/transmitter enabling device as in claim 1, wherein the consumer product is an audio receiver and the plurality of signals contain audio data and the unique operational features are audio playback of the audio data.

6. The receiver/transmitter enabling device as in claim 1, wherein the consumer product is one of a family of consumer products each being configured to be coupled to the data transferring component of the receiver/transmitter enabling device and the plurality of signals are a plurality of RF signals.

7. The receiver/transmitter enabling device as in claim 6, wherein the family of consumer products comprises any combination of the following: personal digital assistants (PDAs); computer systems; communication systems; vehicle systems; home entertainment systems; cameras or other video devices; and hand held entertainment devices, wherein any one of the family of consumer products are configured to communicate with an Internet service provider (ISP).

8. The receiver/transmitter enabling device as in claim 7, wherein the microprocessor comprises machine-readable code for implementing the steps of:
searching for the consumer product, which is one of a family of consumer products each being configured to communicate with the receiver/transmitter enabling device;
establishing a communication link between the consumer product and the receiver/transmitter enabling device;
inquiring whether an account is to be accessed on the consumer product; and
providing an authorization identifier to the consumer product to allow for access to the account through the consumer product, wherein the authorization identifier is an encrypted digital certificate.

9. The receiver/transmitter enabling device as in claim 1, wherein the data transferring component is a USB connector mounted to the housing.

10. A receiver/transmitter for a consumer product having unique operational features, comprising:
a microprocessor programmed to a numerical identifier associated with the consumer product;
a housing for housing the microprocessor, the housing being separable from the consumer product;
a data transferring component coupled to the microprocessor and configured for communicating with the consumer product;
a receiver circuit disposed within the housing;
a transmitter circuit disposed within the housing;
wherein the microprocessor comprises programmable logic that enables a plurality of signals corresponding to the numerical identifier to be received and transmitted between the consumer product and the receiver/transmitter, wherein the consumer product comprises electrical components necessary to facilitate the receipt and transmission of the plurality of signals, wherein linear dimensions and configurations of the consumer product are not constrained by the microprocessor, the data transferring component, the receiver circuit and the transmitter circuit of the receiver/transmitter and the receiver/transmitter is a stand alone device not capable of providing any of the unique operational features of the consumer product.

11. The receiver/transmitter as in claim 10, wherein the consumer product is a video display and the plurality of signals are a subscription of video programming for display on the video display and the unique operational features are video display of the plurality of signals.

12. The receiver/transmitter as in claim 10, wherein the consumer product is one of a family of consumer products each being configured to be coupled to the data transferring component and the microprocessor comprises machine-readable code for implementing the steps of:
searching for the consumer product by transmitting radio waves at a frequency of between 2.402 GHz and 2.480 GHz, wherein the consumer product is one of a family of consumer products each being configured to communicate with the receiver/transmitter;
establishing a communication link between the consumer product and the receiver/transmitter to create a linked consumer product wherein data is exchanged between the consumer product and the receiver/transmitter;
inquiring whether an account is to be accessed on the consumer product; and
providing the numerical identifier to the consumer product to allow for access to the account, wherein the numerical identifier is an encrypted digital certificate.

13. The receiver/transmitter as in claim 12, wherein the family of consumer products comprises any combination of the following: personal digital assistants (PDAs); computer systems; communication systems; vehicle systems; home entertainment systems; cameras or other video devices; and hand held entertainment devices, wherein any one of the family of consumer products are configured to communicate with an Internet service provider (ISP).

14. The receiver/transmitter as in claim 13, wherein the receiver/transmitter is configured to be incorporated into a wearable article of clothing.

15. The receiver/transmitter as in claim 14, wherein the data transferring component is an antenna for wirelessly transmitting and receiving the plurality of signals.

16. The receiver/transmitter as in claim 12, wherein the data transferring component is a USB connector mounted to the housing.

17. A system for receipt and transmission of a plurality of signals, the system comprising:
a family of consumer products each being configured to exchange data with a portable receiver/transmitter, wherein the portable receiver/transmitter, comprises:
a microprocessor programmed to a numerical identifier associated with each of the family of consumer products and each of the family of consumer products provides unique operational features;
a housing for housing the microprocessor, the housing being separable from the consumer product;
a data transferring component coupled to the microprocessor and configured for communicating with each of the family of consumer products;
a receiver circuit disposed within the housing;
a transmitter circuit disposed within the housing;
wherein the microprocessor comprises programmable logic that enables a plurality of signals corresponding to the numerical identifier to be received and transmitted between each of the family of consumer products and the portable receiver/transmitter, wherein each of the family of consumer products comprises electrical components necessary to facilitate the receipt and transmission of the plurality of signals and the microprocessor further comprises machine-readable code for implementing the steps of:
searching for at least one of the family of consumer products by transmitting radio waves at a frequency in a predetermined range;
establishing a communication link between at least one of the family of consumer products and the receiver/transmitter to create a linked consumer product wherein data is exchanged between the linked consumer product and the receiver/transmitter;
inquiring whether an account is to be accessed by the linked consumer product utilizing the numerical identifier; and
providing the numerical identifier to the linked consumer product to allow for access to the account, wherein the numerical identifier is an encrypted digital certificate; and
wherein linear dimensions and configurations of the consumer product are not constrained by the microprocessor, the data transferring component, the receiver circuit and the transmitter circuit of the portable receiver/transmitter.

18. The system as in claim 17, wherein the family of consumer products comprises any combination of the following: personal digital assistants (PDAs); computer systems; communication systems; vehicle systems; home entertainment systems; cameras or other video devices; and hand held entertainment devices, wherein at least one of the family of consumer products is configured to communicate with an Internet service provider (ISP) and wherein each of the family of consumer products is not capable of operating unless the numerical identifier is received from the portable receiver/transmitter.

19. The system as in claim 17, wherein the receiver/transmitter is configured to be incorporated into an article of clothing and wherein the data transferring component is an antenna for transmitting and receiving the plurality of signals, and the receiver/transmitter is a stand alone device not capable of providing any of the unique operational features of the family of consumer products.

20. A method for accessing a plurality of consumer products with a single receiver/transmitter, comprising:
searching for at least one of the plurality of consumer products by transmitting radio waves from the receiver/transmitter;
establishing a communication link between at least one of the consumer products and the receiver/transmitter to create a linked consumer product wherein data is exchanged between the linked consumer product and the receiver/transmitter;
inquiring whether an account is to be accessed on the linked consumer product; and
providing a numerical identifier to the linked consumer product to allow for access to the account, wherein the numerical identifier is an encrypted digital certificate and the receiver/transmitter is a stand alone device not capable of providing any of the operational features of the plurality of consumer products.

21. The method as in claim 20, wherein the plurality of consumer products comprises any combination of the following: personal digital assistants (PDAs); computer systems; communication systems; vehicle systems; home entertainment systems; cameras or other video devices; and hand held entertainment devices, wherein any one of the plurality of consumer products are able to access an Internet service provider (ISP).
